(19) United States
(12) Patent Application Publication
(10) Pub. No.: US 2024/0164036 A1
(43) Pub. Date: May 16, 2024

(54) COVER WITH RING FOR FOLDABLE ELECTRONIC DEVICE

(71) Applicant: Samsung Electronics Co., Ltd., Suwon-si (KR)

(72) Inventors: Bosoon KANG, Suwon-si (KR); Namsu KIM, Suwon-si (KR); Dahyun LEE, Suwon-si (KR); Junho JIN, Suwon-si (KR)

(21) Appl. No.: 18/421,240

(22) Filed: Jan. 24, 2024

Related U.S. Application Data
(63) Continuation of application No. PCT/KR2022/011174, filed on Jul. 29, 2022.

(30) Foreign Application Priority Data
Jul. 30, 2021 (KR) 10-2021-0100990

(51) Int. Cl. H05K 5/03; H05K 5/02

(52) U.S. Cl. CPC H05K 5/03; H05K 5/0226

(57) ABSTRACT

A cover for a foldable electronic device is provided. The cover includes a first cover member and a second cover member, wherein the first cover member and the second cover member are spaced a certain interval from each other and are configured to be folded or unfolded with a folding axis interposed therebetween, an inner cover includes a first area coupled to a first inner surface of the first cover member, a second area coupled to a second inner surface of the second cover member, and a third area connecting the first area and the second area and extending across the certain interval, and a ring coupled to the third area of the inner cover.

### CROSS-REFERENCE TO RELATED APPLICATION(S)

This application is a continuation application, claiming priority under § 365(c), of an International application No. PCT/KR2022/011174, filed on Jul. 29, 2022, which is based on and claims the benefit of a Korean patent application number 10-2021-0100990, filed on Jul. 30, 2021, in the Korean Intellectual Property Office, the disclosure of which is incorporated by reference herein in its entirety.

### BACKGROUND

### 1. Field

The disclosure relates to a cover with a ring for a foldable electronic device.

### 2. Description of Related Art

A cover for a foldable electronic device may cover a foldable electronic device. For example, the cover covers a portion of the foldable electronic device excluding a display region. The cover may protect the foldable electronic device from external shock. The foldable electronic device may include a flexible display. A flexible display may be formed to be bendable, with at least some regions formed as curved or flat surfaces. The foldable electronic device may include a first housing coupled to one side and a second housing coupled to the other side based on a bending region of the flexible display. The foldable electronic device may include a hinge structure that foldably connects the first housing and the second housing, and a hinge housing that covers the hinge structure.

The above information is presented as background information only to assist with an understanding of the disclosure. No determination has been made, and no assertion is made, as to whether any of the above might be applicable as prior art with regard to the disclosure.

### SUMMARY

The cover for a foldable electronic device may be composed of two cover members that are separately coupled to the first housing and the second housing, respectively. The two cover members may not cover the hinge housing. The two cover members are likely to be relatively easily removed from the first housing and the second housing, respectively, when the foldable electronic device is in a folded state.

Aspects of the disclosure are to address at least the above-mentioned problems and/or disadvantages and to provide at least the advantages described below. Accordingly, an aspect of the disclosure is to provide a cover for a foldable electronic device, capable of being firmly coupled to a housing and providing an improved grip.

Additional aspects will be set forth in part in the description which follows and, in part, will be apparent from the description, or may be learned by practice of the presented embodiments.

In accordance with an aspect of the disclosure, a cover for an electronic device is provided. The cover includes a first cover member and a second cover member that are spaced apart at a predetermined interval and configured to be folded and unfolded with a folding axis therebetween, an inner cover including a first region coupled to a first inner surface of the first cover member, a second region coupled to a second inner surface of the second cover member, and a third region extending across the predetermined interval while connecting the first region and the second region, and a ring coupled to the third region of the inner cover.

In accordance with another aspect of the disclosure, a cover for an electronic device is provided. The cover includes a folded state in which a first housing and a second housing face each other and an unfolded state in which the first housing and the second housing are arranged side by side. The cover includes a first cover member configured to be coupled to the first housing, a second cover member configured to be coupled to the second housing, the second cover member being spaced apart from the first cover member at a predetermined distance, an inner cover including a first region positioned between the first housing and the first cover member, a second region positioned between the second housing and the second cover member, and a third region extending from the first region to the second region, and a ring coupled to the third region, and the third region of the inner cover includes a flexible region to which the ring is coupled and that is configured so that its shape is deformed when the electronic device is folded and unfolded.

A cover according to embodiments disclosed herein is configured so that a user is able to easily hold the cover and an electronic device by providing a ring. In addition, the cover is configured so that two cover members are firmly coupled without sliding down from two respective housings of the electronic device, using a load applied to a ring on which the user's finger hangs.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating a foldable electronic device to which a cover for a foldable electronic device according to an embodiment of the disclosure;

FIG. 2 is a view illustrating a foldable electronic device to which a cover for a foldable electronic device according to an embodiment of the disclosure:

FIG. 3 is a view illustrating a cover for an electronic device according to an embodiment of the disclosure;

FIG. 4 is a view illustrating an inner cover of a cover for an electronic device according to an embodiment of the disclosure;

FIG. 5 is a view illustrating a third region of an inner cover of a cover for an electronic device according to an embodiment of the disclosure;

FIG. 6 is a view illustrating an unfolded state of the cover for an electronic device according to an embodiment of the disclosure;

FIG. 7 is a view illustrating a folded state of a cover for an electronic device according to an embodiment of the disclosure;

FIG. 8 is a view illustrating an inside of a cover for an electronic device according to an embodiment of the disclosure;

FIG. 9 is a cross-sectional view of a cover for an electronic device according to an embodiment of the disclosure;

FIG. 10 is a view illustrating a cover for an electronic device in a folded state according to an embodiment of the disclosure;

FIG. 11 is a view illustrating a cover for an electronic device in a folded state according to an embodiment of the disclosure;

FIG. 12 is a view illustrating a cover for an electronic device according to an embodiment of the disclosure;

FIG. 13 is a view illustrating a cover for an electronic device according to an embodiment of the disclosure; and

FIG. 14 is a view illustrating a folded state in which an electronic device is coupled to a cover for an electronic device according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, hose of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory or the one or more computer programs may be divided with different portions stored in different multiple memories.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display drive integrated circuit (IC), an audio CODEC chip, a universal serial bus (USB) controller, a camera controller, an image processing IC, a microprocessor unit (MPU), a system on chip (SoC), an integrated circuit (IC), or the like.

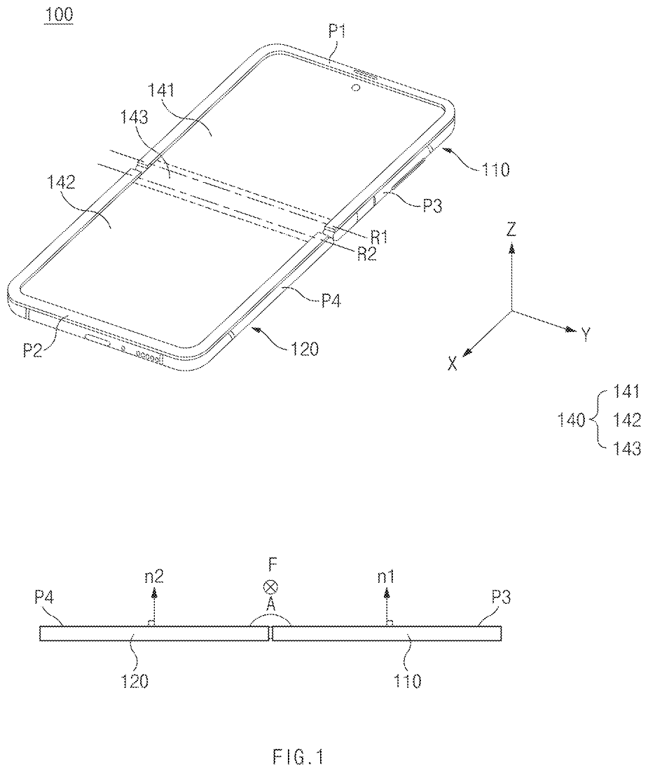

FIG. 1 is a view illustrating a foldable electronic device to which a cover according to an embodiment of the disclosure.

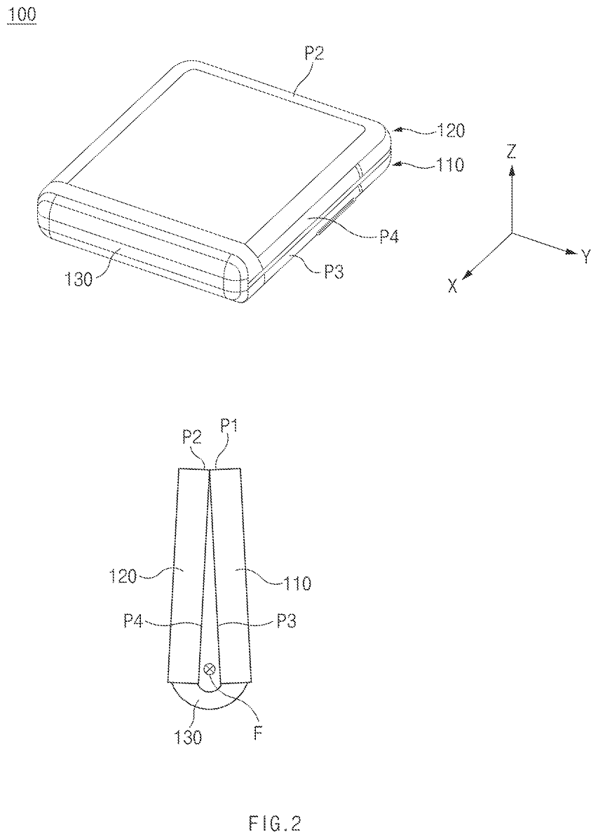

FIG. 2 is a view illustrating a foldable electronic device to which a cover according to an embodiment of the disclosure.

Referring to FIGS. 1 and 2, in an embodiment, a foldable electronic device (hereinafter referred to as an electronic device) may include a first housing 110, a second housing 120, a hinge housing 130, and a display 140.

In an embodiment, the first housing 110 and the second housing 120 may rotate in opposite directions by their respective rotation axes R1 and R2. For example, in a folding operation for moving from an unfolded state of FIG. 1 to a folded state of FIG. 2, the first housing 110 rotates clockwise or counterclockwise, and the second housing 120 may rotate counterclockwise or clockwise. In another embodiment, the rotation axis R1 of the first housing 110 and the rotation axis R2 of the second housing 120 each extend in an X-axis direction and may be parallel to each other. In various embodiments, each of the rotation axes R1 and R2 may be provided by a hinge structure (not illustrated).

Referring to FIG. 2, the hinge housing 130 may be disposed between the first housing 110 and the second housing 120. The hinge housing 130 may be covered by the first housing 110 and the second housing 120 in an unfolded state. The hinge housing 130 may be exposed to the outside in a folded state. The hinge housing 130 may be provided in a shape entirely extending longitudinally in the X-axis direction. A hinge structure (not illustrated) for rotating the first housing 110 and the second housing 120 may be disposed inside the hinge housing 130.

In yet another embodiment, the display 140 may be provided to be at least partially flexible. In yet another embodiment, the display 140 may include a first region 141, a second region 142, and a folding region 143. The first region 141 and the second region 142 may include a flat surface in each of the unfolded state and the folded state. The folding region 143 may include a curved surface in the folded state and a flat surface in the unfolded state. The first region 141 may be at least partially disposed in the first housing 110, and the second region 142 may be at least partially disposed in the second housing 120. The folding region 143 may be defined between the first region 141 and the second region 142. The folding region 143 may be transformed into a flat or curved surface at the time of a folding or unfolding operation of the electronic device 100.

To describe a state of the electronic device 100, a first edge P1 of the electronic device 100 and a second edge P2 of the electronic device 100 parallel to the axis direction may be defined. To describe the state of the electronic device 100, a third edge P3 of the electronic device 100 and a fourth edge P4 of the electronic device 100 perpendicular to the axis direction may be defined.

In yet another embodiment, the electronic device 100 may be configured so that the first housing 110 and the second housing 120 are folded or unfolded with a folding axis F interposed therebetween. In this case, the folding region 143 of the display 140 may be transformed into the curved surface or the flat surface. For example, the folding axis F is a virtual axis parallel to each of the rotation axis R1 of the first housing 110 and the rotation axis R2 of the second housing 120.

The unfolded state of the electronic device 100 will be described with reference to FIG. 1. The unfolded state may include a state in which the folding region 143 of the display 140 is substantially flat. For example, the unfolded state includes a state in which the first region 141 and the second region 142 of the display 140 are formed to be flat surfaces facing the same direction. For example, the unfolded state includes a state in which the first region 141, the second region 142, and the folding region 143 of the display 140 form one substantially flat surface. For example, the unfolded state includes a state in which a first normal vector n1 of the first region 141 of the display 140 and a second normal vector n2 of the second region 142 are parallel. For example, the unfolded state includes a state in which the third edge P3 and the fourth edge P4 substantially form one straight line. For example, the unfolded state includes a state in which the third edge P3 and the fourth edge P4 form an angle of 180 degrees.

The folded state of the electronic device will be described with reference to FIG. 2. For example, the folded state means a state in which the first edge P1 and the second edge P2 are substantially in contact with each other. For example, the folded state means a state in which the first edge P1 and the second edge P2 are at least partially in contact with each other. For example, the folding region 143 is formed to be a curved surface in the folded state. In the folded state, the hinge housing 130 may form at least a portion of the surface of the electronic device 100. For example, the hinge housing 130 is visually exposed between the first housing 110 and the second housing 120. A region of the hinge housing 130 visually exposed between the first housing 110 and the second housing 120 may be wider in the folded state than in the unfolded state.

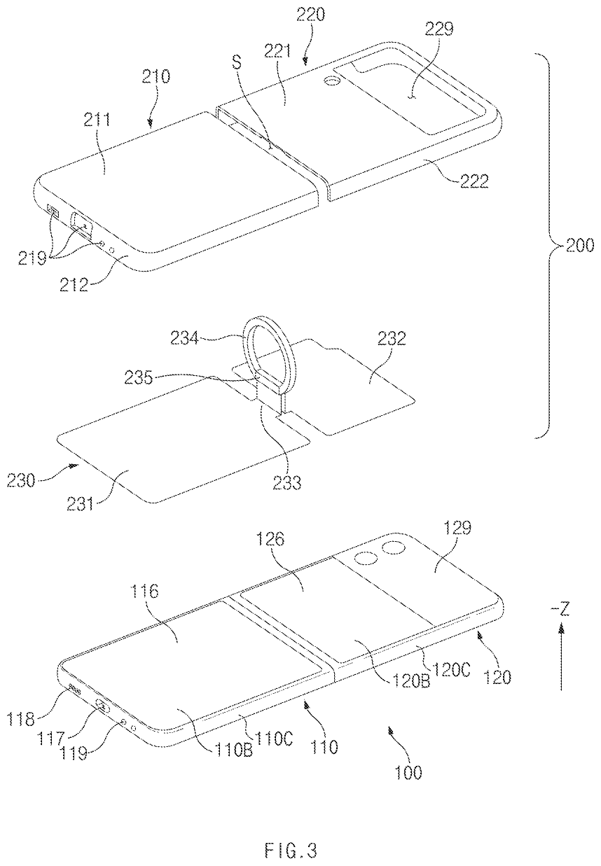

FIG. 3 is a view illustrating a cover for an electronic device according to an embodiment of the disclosure.

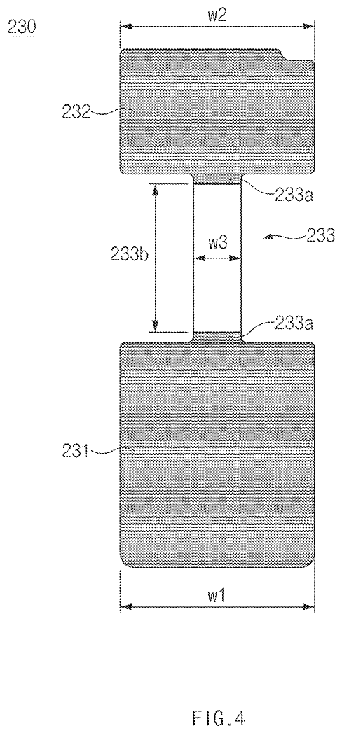

FIG. 4 is a view illustrating an inner cover of the cover for an electronic device according to an embodiment of the disclosure.

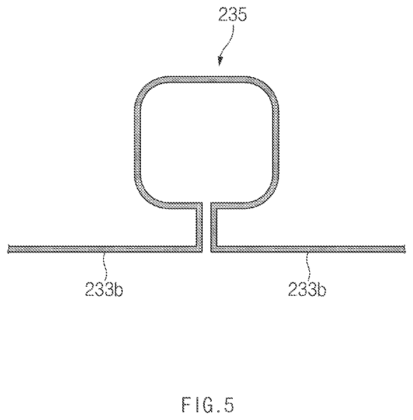

FIG. 5 is a view illustrating a third region of an inner cover of a cover for an electronic device according to an embodiment of the disclosure.

Referring to FIG. 3, the cover 200 may include a first cover member 210, a second cover member 220, an inner cover 230, and a ring 234.

In an embodiment, the first cover member 210 may be coupled to the first housing 110 of the electronic device 100. In another embodiment, the first cover member 210 may be provided to surround at least a portion of the first housing 110 of the electronic device 100. For example, the first cover member 210 covers at least a portion of each of a back surface 110B and a side surface 110C of the first housing 110. For example, the first cover member 210 at least partially covers a first back cover 116 of the first housing 110. In yet another embodiment, the first cover member 210 may include a first portion 211 that covers at least a portion of the back surface 110B of the first housing 110, and a second portion 212 that covers at least a portion of the side surface 110C of the first housing 110. The second portion 212 may extend from at least a portion of an edge of the first portion 211. The first portion 211 may at least partially face the first back cover 116 of the first housing 110. In yet another embodiment, a first region 231 of the inner cover 230 may be disposed between the first portion 211 of the first cover member 210 and the first back cover 116. In yet another embodiment, in the first cover member 210, first opening regions 219, respectively, corresponding to a speaker hole 118, a microphone hole 119, and a hole 117 into which an external interface terminal is inserted, which are provided in the first housing 110, may be formed. The first opening regions 219 may be formed in the second portion 212 of the first cover member 210. For example, the external interface terminal includes a universal series bus (USB) terminal. However, the first opening regions 219 may be formed in the first portion 211 and/or the second portion 212 of the first cover member 210 depending on positions of various modules provided in the electronic device 100.

In yet another embodiment, the second cover member 220 may be coupled to the second housing 120 of the electronic device 100. In yet another embodiment, the second cover member 220 may be provided to surround at least a portion of the second housing 120 of the electronic device 100. For example, the second cover member 220 covers at least a portion of each of a back surface 120B and a side surface 120C of the second housing 120. For example, the second cover member 220 at least partially covers a second back cover 126 of the second housing 120. In yet another embodiment, the second cover member 220 may include a third portion 221 that covers at least a portion of the back surface 120B of the second housing 120 and a fourth portion 222 that covers at least a portion of the side surface 120C of the second housing 120. The fourth portion 222 may extend from at least a portion of an edge of the third portion 221. The third portion 221 may at least partially face the second back cover 126 of the second housing 120. In yet another embodiment, a second region 232 of the inner cover 230 may be disposed between the third portion 221 of the second cover member 220 and the second back cover 126. In yet another embodiment, a second opening region 229 corresponding to a camera region 129 provided in the second housing 120 may be formed in the second cover member 220. Referring to the drawing, the second opening region 229 may be formed in the third portion 221 of the second cover member 220. However, the second opening region 229 may be formed in the third portion 221 and/or the fourth portion 222 of the second cover member 220 depending on positions of various modules provided in the electronic device 100.

In yet another embodiment, the first cover member 210 and the second cover member 220 may be spaced apart at a predetermined interval so that a space S is formed therebetween. The ring 234 of the inner cover 230 and at least a portion of the third region 233 may be positioned in the space S. For example, the ring 234 is exposed in a rear direction (e.g., a −Z-axis direction) through the space S.

Referring to FIGS. 3, 4, and 5, the inner cover 230 may include the first region 231, the second region 232, the third region 233, and the ring 234.

In yet another embodiment, the first region 231 may be positioned between the first housing 110 and the first cover member 210. For example, the first region 231 is disposed between the first back cover 116 of the first housing 110 and the first portion 211 of the first cover member 210. The first region 231 may be connected to the second region 232 through the third region 233. When viewed in the rear direction (e.g., the −Z-axis direction), the first region 231 may be formed to be smaller than the first portion 211 of the first cover member 210.

In yet another embodiment, the second region 232 may be positioned between the second housing 120 and the second cover member 220. For example, the second region 232 is disposed between the second back cover 126 of the second housing 120 and the third portion 221 of the second cover member 220. The second region may be connected to the first region 231 through the third region 233. When viewed in the rear direction (the −Z-axis direction), the second region 232 may be formed to be smaller than the third portion 221 of the second cover member 220.

In yet another embodiment, the third region 233 may connect the first region 231 and the second region 232. The third region 233 may extend across the space S between the first cover member 210 and the second cover member 220. The ring 234 may be coupled to the third region 233 including a coupling portion 235. The ring 234 may be coupled to the third region 233 through the coupling portion 235. For example, the coupling portion 235 extends from the third region 233 to at least partially surround the ring 234. The coupling portion 235 may be formed in a completely closed ring shape, or may be formed in a partially open ring shape. The coupling portion 235 may be exposed in the rear direction (e.g., the −Z-axis direction) through a space between the first cover member 210 and the second cover member 220.

In yet another embodiment, the ring 234 may be coupled to the coupling portion 235 of the third region 233. The ring 234 may be positioned toward the rear in the unfolded state. A user may hold the electronic device 100 by hooking his or her finger on the ring 234. In various embodiments, at least a portion of the ring 234 may be formed as a straight section. For example, the coupling portion 235 of the third region 233 is coupled to the straight section.

In yet another embodiment, the third region 233 of the inner cover 230 may be configured to have a smaller width than the first region 231 and/or the second region 232. For example, the first region 231 has a first width w1, the second region 232 may have a second width w2, and the third region 233 may have a third width w3 smaller than the first width w1 and/or the second width w2.

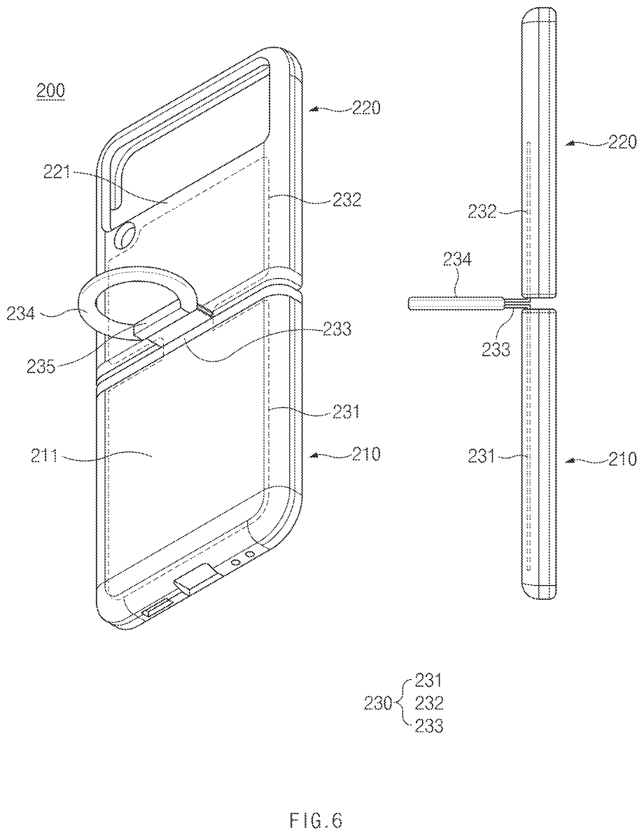

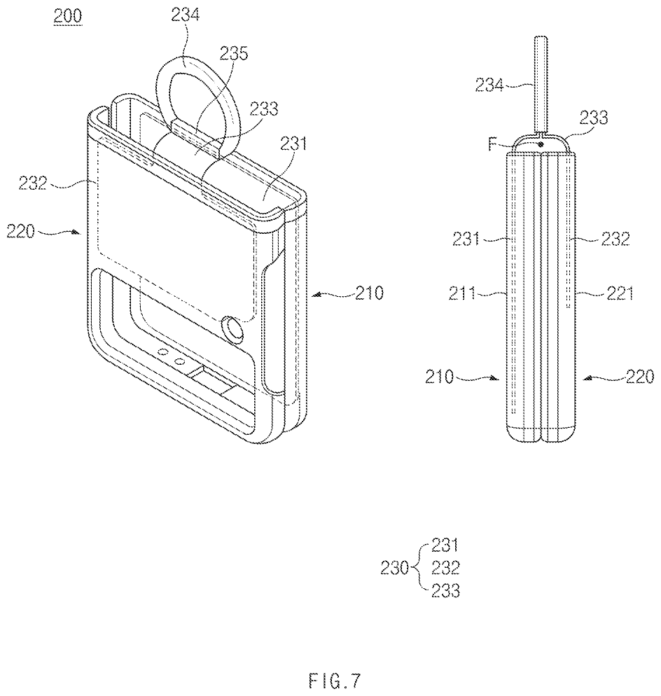

In yet another embodiment, the third region 233 may include a rigid region 233a and a flexible region 233b. The rigid region 233a of the third region 233 may include a region connected to the first region 231 and the second region 232. The flexible region 233b may be formed between the rigid regions 233a. The flexible region 233b may have different shapes depending on whether the cover 200 is in the unfolded state (e.g., FIG. 6) or the folded state (e.g., FIG. 7). The flexible region 233b may be configured to bent depending on whether the cover 200 is in the unfolded state or the folded state. For example, the flexible region 233b is overlapped to face itself in the unfolded state, and is relatively tight and formed as a round curved surface in the folded state.

In various embodiments, the flexible region 233b may include the coupling portion 235 to which the ring 234 is coupled, or the coupling portion 235 may be connected to the flexible region 233b. For example, the flexible region 233b is formed integrally with the coupling portion 235 or may be formed separately from the coupling portion 235. For example, the coupling portion 235 is made of a flexible material and form a portion of the flexible region 233b, or is formed of a hard material to maintain the shape of the coupling portion 235 and separately connected to the flexible region 233b.

FIG. 6 is a view illustrating an unfolded state of a cover for an electronic device according to an embodiment of the disclosure.

FIG. 7 is a view illustrating a folded state of a cover for an electronic device according to an embodiment of the disclosure.

Referring to FIGS. 6 and 7, the cover 200 may be configured so that the first cover member 210 and the second cover member 220 are folded or unfolded in response to the operation of the electronic device 100 being unfolded or folded. For example, when the cover 200 is unfolded or folded, the third region 233 of the inner cover 230 is deformed. When the cover 200 is unfolded or folded, the third region 233 of the inner cover 230 may be partially unfolded or folded with the folding axis F in the middle.

Referring to FIG. 6, the unfolded state may include a state corresponding to the unfolded state (e.g., FIG. 1) of the electronic device 100. For example, the unfolded state of the cover 200 includes a state in which a flat part included in the first portion 211 of the first cover member 210 and a flat part included in the second portion 212 of the second cover member 220 form substantially the same plane. For example, the unfolded state includes a state in which the first portion 211 of the first cover member 210 and the second portion 212 of the second cover member 220 are arranged side by side to face the rear direction (e.g., the −Z-axis direction in FIG. 3). For example, the unfolded state includes a state in which the first region 231 and the second region 232 of the inner cover 230 form substantially the same plane.

Referring to FIG. 7, the folded state may include a state corresponding to the folded state (e.g., FIG. 2) of the electronic device 100. For example, the folded state of the cover 200 includes a state in which the first portion 211 of the first cover member 210 and the second portion 212 of the second cover member 220 face each other. For example, the folded state includes a state in which the first region 231 and the second region 232 of the inner cover 230 face each other.

Referring to the unfolded state in FIG. 6, at least a portion of the third region 233 of the inner cover 230 may extend into a space (e.g., the space S in FIG. 3) between the first cover member 210 and the second cover member 220. For example, the flexible region 233b of the third region 233 extends in the rear direction through the space between the first cover member 210 and the second cover member 220. The ring 234 may be coupled to the flexible region 233b of the third region 233. The flexible region 233b may be configured to surround a portion of the ring 234. In the unfolded state, the flexible region 233b may have a form in which a portion of the flexible region 233b overlaps another portion. For example, the flexible region 233b includes a planar region overlapping itself.

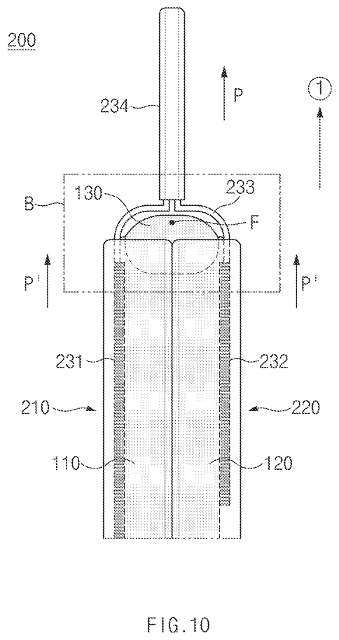

Referring to the folded state in FIG. 7, the first cover member 210 and the second cover member 220 may be arranged in an overlapping state. In the folded state of the cover on which the electronic device 100 is mounted, the hinge housing (e.g., the hinge housing 130 in FIG. 2 or the hinge housing 130 in FIG. 10) may be visually exposed through the space between the first cover member 210 and the second cover member 220. In an embodiment, the third region 233 of the inner cover 230 may be bent into a round shape in the folded state. In another embodiment, at least a portion of the third region 233 (e.g., the flexible region 233b) may be made of a flexible material so as to be bent roundly in the folded state and to overlap itself in the unfolded state. In an embodiment, the third region 233 may be formed with a sufficient length to extend along the surface of the hinge housing (e.g., the hinge housing 130 in FIG. 10) in the folded state.

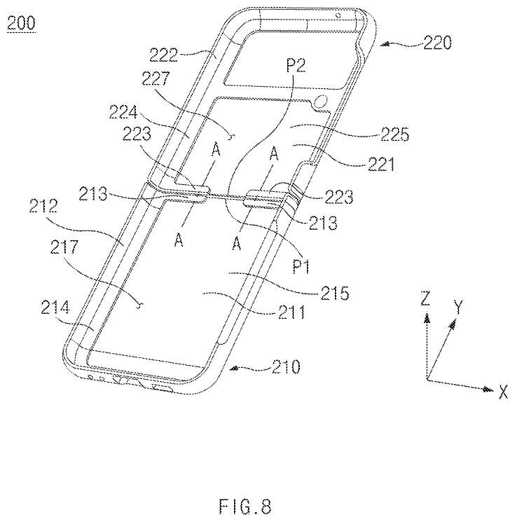

FIG. 8 is a view illustrating the inside of a cover for an electronic device according to an embodiment of the disclosure.

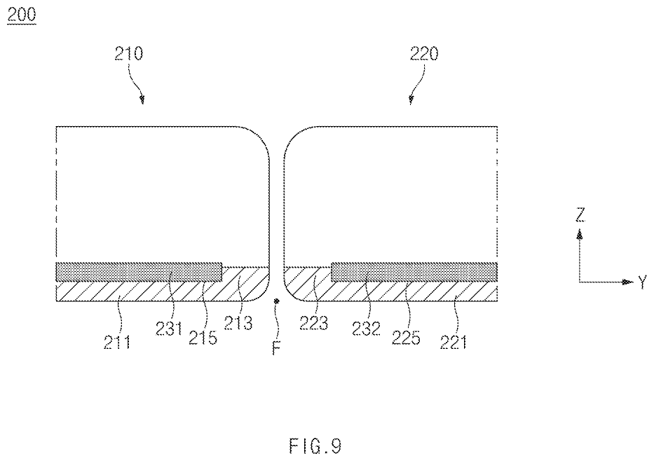

FIG. 9 is a cross-sectional view taken along line A-A′ of FIG. 8 according to an embodiment of the disclosure.

FIG. 10 is a view illustrating a cover for an electronic device in a folded state according to an embodiment of the disclosure.

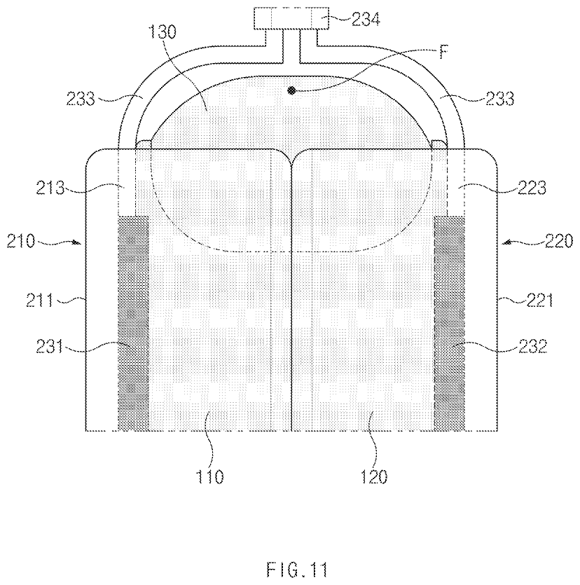

FIG. 11 is an enlarged view of part B of FIG. 10 according to an embodiment of the disclosure.

Referring to FIG. 8, a first cover member 210 may include a first portion 211, and a second portion 212 extending from a portion of an edge of the first portion 211 to form a space in which a first housing (e.g., the first housing 110 in FIG. 2) of an electronic device 100 is disposed.

The first cover member 210 may have an open shape in a direction toward a second cover member 220. For example, the second portion 212 of the first cover member 210 is provided at an edge of the first portion 211 in a −Y-axis direction and an edge of the first portion 211 in a +X/−X-axis direction, and may not be provided at an edge thereof in a +Y-axis direction which is adjacent to the second cover member 220.

In the first portion 211, a first inner surface 215 on which a first region 231 of an inner cover 230 is positioned may be defined. For example, in an unfolded state, the first inner surface 215 is a plane facing the +Z-axis direction. A first recess 217 in which the first region 231 of the inner cover 230 is positioned may be formed on the first inner surface 215. The first recess 217 may include a recessed region in the −Z-axis direction. For example, a first side wall 213 surrounding at least a portion of the edge of the first region 231 of the inner cover 230 is formed on the first inner surface 215. In an embodiment, the first side wall 213 may be positioned adjacent to an open portion of the first cover member 210. For example, the first side wall 213 is positioned adjacent to the edge in the +Y-axis direction. The first side wall 213 may extend longitudinally in the X-axis direction. For example, the first side wall 213 contacts an edge of the first region 231 of the inner cover 230 that is parallel to the X-axis.

In another embodiment, in the first portion 211 of the first cover member 210, a first edge P1 parallel to the X-axis and adjacent to the second cover member 220 may be defined. At least a portion of the first side wall 213 may extend along a portion of the first edge P1 or may be formed at a position adjacent to the first edge P1. The first side wall 213 may be formed so that a portion corresponding to the third region 233 of the inner cover 230 is open. The third region 233 may extend into a second region 232 through the open portion.

In yet another embodiment, a second side wall 214 extending from the first side wall 213 in the Y-axis direction may be additionally formed in the first portion 211 of the first cover member 210. For example, the second side wall 214 contacts an edge of the first region 231 of the inner cover 230 that is parallel to the Y-axis. In yet another embodiment, the first side wall 213 and the second side wall 214 may form the first recess 217. The first side wall 213 and the second side wall 214 may have a shape that substantially protrudes in the +Z-axis direction.

In various embodiments, the first side wall 213 of the first cover member 210 may extend in a direction substantially parallel to a folding axis F of the cover 200. The first side wall 213 may be configured to support an edge of the first region 231 of the inner cover 230 that is parallel to the folding axis F and adjacent to the folding axis F.

The second cover member 220 may include a third portion 221 on which the second region 232 of the inner cover 230 is disposed, and a fourth portion 222 extending from a portion of an edge of the third portion 221 to form a space in which a second housing (e.g., the second housing 120 in FIG. 3) of the electronic device 100 is disposed.

The second cover member 220 may have an open shape in a direction toward the first cover member 210. For example, the fourth portion 222 of the second cover member 220 is provided at an edge of the third portion 221 in the +Y-axis direction and an edge of the third portion 221 in a +X/−X-axis direction, and is not provided at an edge thereof in the −Y-axis direction which is adjacent to the first cover member 210.

In the third portion 221, a second inner surface 225 on which the second region 232 of the inner cover 230 is positioned may be defined. For example, in the unfolded state, the second inner surface 225 is a plane facing the +Z-axis direction. A second recess 227 in which the second region 232 of the inner cover 230 is positioned may be formed on the second inner surface 225. The second recess 227 may include a recessed region in the −Z-axis direction. For example, a third side wall 223 surrounding at least a portion of the edge of the second region 232 of the inner cover 230 is formed on the second inner surface 225. In yet another embodiment, the third side wall 223 may be positioned adjacent to an open portion of the second cover member 220. For example, the third side wall 223 is positioned adjacent to the edge in the −Y-axis direction. The third side wall 223 may extend longitudinally in the X-axis direction. For example, the third side wall 223 contacts an edge of the second region 232 of the inner cover 230 that is parallel to the X-axis.

In yet another embodiment, in the third portion 221 of the second cover member 220, a second edge P2 parallel to the X-axis and adjacent to the first cover member 210 may be defined. At least a portion of the third side wall 223 may extend along a portion of the second edge P2 or may be formed at a position adjacent to the second edge P2. The third side wall 223 may be formed so that a portion corresponding to the third region 233 of the inner cover 230 is open. The third region 233 may extend into the first region 231 through the open portion.

In yet another embodiment, a fourth side wall 224 extending from the third side wall 223 in the Y-axis direction may be additionally formed in the third portion 221 of the second cover member 220. For example, the fourth side wall 224 contacts an edge of the second region 232 of the inner cover 230 that is parallel to the Y-axis. In yet another embodiment, the third side wall 223 and the fourth side wall 224 may form the second recess 227. The third side wall 223 and the fourth side wall 224 may have a shape that substantially protrudes in the +Z-axis direction.

In various embodiments, the third side wall 223 of the second cover member 220 may extend in a direction substantially parallel to the folding axis F of the cover 200. The third side wall 223 may be configured to support an edge of the second region 232 of the inner cover 230 that is parallel to the folding axis F and adjacent to the folding axis F.

Referring to the cross-sectional view of FIG. 9, the first side wall 213 formed on the first inner surface 215 of the first cover member 210 and the third side wall 223 formed on the second inner surface 225 of the second cover member 220 may be positioned between the first region 231 of the inner cover 230 and the second region 232 of the inner cover 230.

Referring to FIG. 10, in the folded state, the hinge housing 130 may constitute a portion of the surface of the electronic device 100. The hinge housing 130 may be exposed to a space between the first cover member 210 and the second cover member 220. At least a portion (e.g., the flexible region 233b in FIG. 4) of the third region 233 of the inner cover 230 may be disposed to partially cover the hinge housing 130 of the electronic device 100. In FIG. 10, the hinge housing 130 and the third region 233 of the inner cover 230 are illustrated as being spaced apart, but the configuration thereof is not necessarily limited thereto. For example, the third region 233 of the inner cover 230 partially contacts the hinge housing 130.

Referring to FIGS. 10 and 11, a first direction \textcircled{1} may be defined for the cover 200 in the folded state. The first direction \textcircled{1} may be a direction in which the first cover member 210 and the second cover member 220 are opened. For example, the first direction \textcircled{1} is a direction from the first cover member 210 or the second cover member 220 toward the ring 234. For example, the first direction \textcircled{1} is a direction from the first region 231 or the second region 232 of the inner cover 230 toward the third region 233. The first direction \textcircled{1} may be perpendicular to the folding axis F.

In yet another embodiment, a user may hold the electronic device 100 by hooking his or her finger on the ring 234. In this case, a load may be applied the ring 234 in the first direction \textcircled{1}. The load P may be transmitted to the first region 231 and the second region 232 of the inner cover through the third region 233. For example, a load P′ is applied to each of the first region 231 and the second region 232 in the first direction \textcircled{1}. For example, the first direction \textcircled{1} means a direction in which the first cover member 210 and the second cover member 220 are open in the folded state (e.g., a direction in which the second portion 212 and the fourth portion 222 are not formed).

In various embodiments, the first direction \textcircled{1} may mean a direction substantially opposite to the direction of gravity.

In another embodiment, the first region 231 of the inner cover 230 may press the first side wall 213 in the first direction \textcircled{1}. As a reaction to the pressing, the first side wall 213 may press the first region 231 of the inner cover 230 in a direction opposite to the first direction \textcircled{1}. Accordingly, the first side wall 213 provided on the first cover member 210 may prevent the first region 231 of the inner cover 230 from getting out of the first cover member 210. The first side wall 213 may restrict the movement of the first region 231 by at least partially contacting the edge of the first region 231.

Referring to FIG. 10, when the user hooks his or her finger on the ring 234 and lifts and holds the electronic device 100 lying on the ground, gravity may be applied to the first cover member 210 in the direction opposite to the first direction \textcircled{1}. The first cover member 210 may slip down from the first housing 110 of the electronic device 100 due to the gravity.

In yet another embodiment, the first side wall 213 provided inside the first cover member 210 may transmit the load P′ applied to the first region 231 of the inner cover 230 in the first direction \textcircled{1} to the first cover member 210, thereby preventing the first cover member 210 from sliding down from the first housing 110.

In yet another embodiment, the second region 232 of the inner cover 230 may press the third side wall 223 in the first direction \textcircled{1}. As a reaction to the pressing, the third side wall 223 may press the second region 232 of the inner cover 230 in the direction opposite to the first direction \textcircled{1}. Accordingly, the third side wall 223 provided on the second cover member 220 may prevent the second region 232 of the inner cover 230 from getting out of the second cover member 220. The third side wall 223 may restrict the movement of the second region 232 by at least partially contacting the edge of the second region 232.

Referring to FIG. 10, when the user hooks his or her finger on the ring 234 and lifts and holds the electronic device 100 lying on the ground, gravity may be applied to the second cover member 220 in the direction opposite to the first direction \textcircled{1}. The second cover member 220 may slip down from the second housing 120 of the electronic device 100 due to the gravity.

In yet another embodiment, the third side wall 223 provided inside the second cover member 220 may transmit the load P′ applied to the second region 232 of the inner cover 230 in the first direction \textcircled{1} to the second cover member 220, thereby preventing the second cover member 220 from sliding down from the second housing 120.

As described above, the cover 200 according to the embodiments disclosed herein may be easily held by a user by providing the ring 234. In addition, the cover 200 may be configured so that the two cover members 210 and 220 are firmly coupled without sliding down from two housings 110 and 120 of the electronic device 100, respectively, using the load applied to the ring 234.

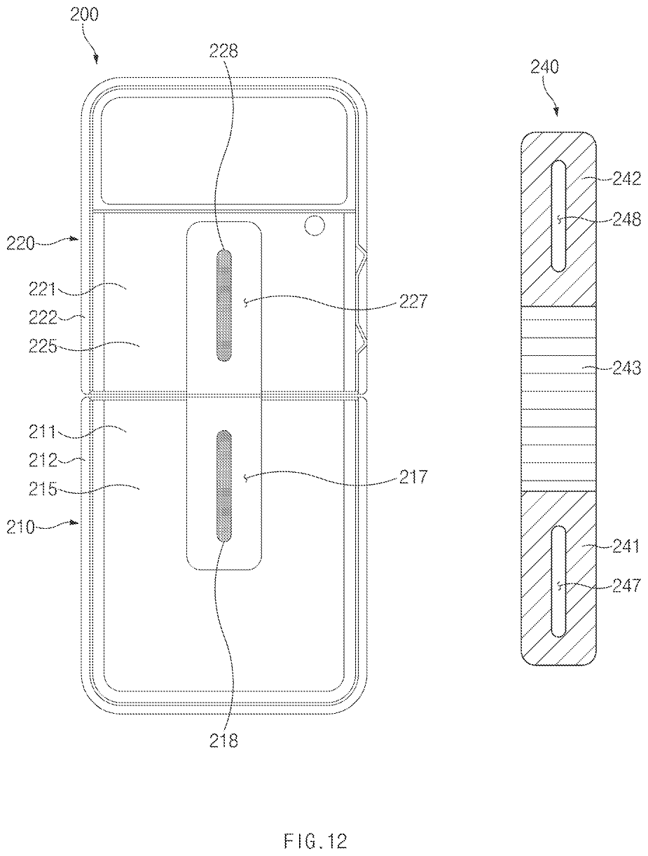

FIG. 12 is a view illustrating a cover for an electronic device according to an embodiment of the disclosure.

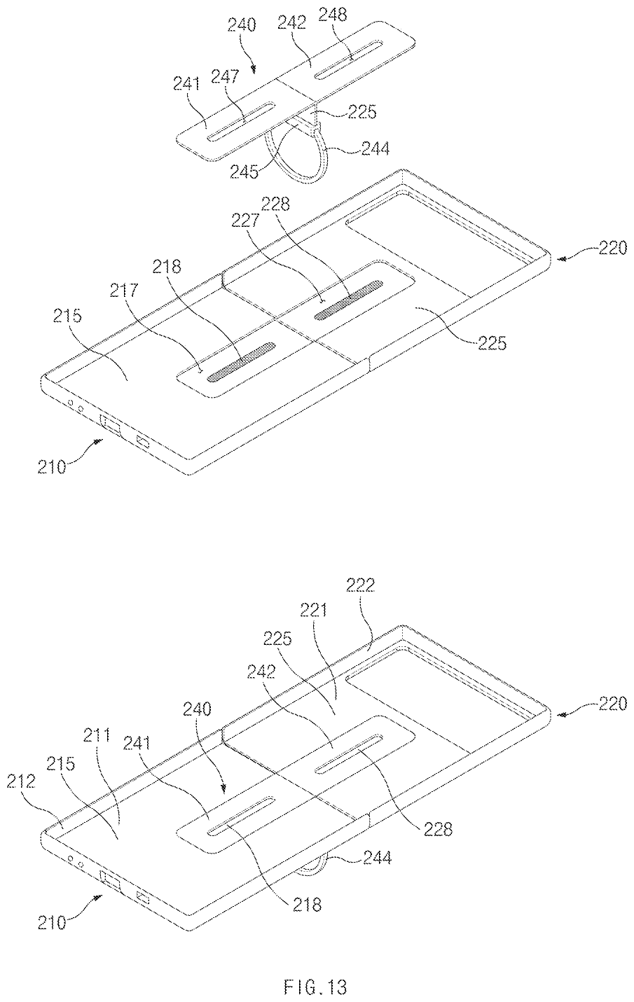

FIG. 13 is a view illustrating a cover for an electronic device according to an embodiment of the disclosure.

Referring to FIGS. 12 and 13, in an embodiment, a cover 200 may include the first cover member 210, the second cover member 220, an inner cover 240, and a ring 244.

Referring to FIG. 3 together, the first cover member 210 may be provided to surround at least a portion of the first housing 110 of the electronic device 100. For example, the first cover member 210 is coupled to the first housing 110 to cover at least a portion of each of a back surface 110B and a side surface 110C of the first housing 110. For example, the first cover member 210 at least partially covers the first back cover 116 of the first housing 110. In an embodiment, the first cover member 210 may include a first portion 211 that covers at least a portion of the back surface 110B of the first housing 110, and a second portion 212 that covers at least a portion of the side surface 110C of the first housing 110. The second portion 212 may extend from at least a portion of an edge of the first portion 211. The first portion 211 may at least partially face the first back cover 116 of the first housing 110. In another embodiment, a recessed first recess 217 may be formed in a first inner surface 215 of the first portion 211. A first protrusion 218 may be formed in the first recess 217. For example, the first protrusion 218 protrudes toward the first housing 110 of the electronic device. The first protrusion 218 may form the same plane as the first inner surface 215, which is a surrounding region of the first recess 217. For example, the first protrusion 218 protrudes to the same height as the surrounding region of the first recess 217. The first recess 217 may be recessed to a predetermined depth to form the same plane as the surrounding region of the first recess 217 in a state in which a first region 241 of the inner cover 240 is seated. For example, the first recess 217 is recessed to a depth corresponding to the thickness of the first region 241.

Referring to FIG. 3 together, the second cover member 220 may be provided to surround at least a portion of the second housing 120 of the electronic device 100. For example, the second cover member 220 is coupled to the second housing 120 to cover at least a portion of each of the back surface 120B and the side surface 120C of the second housing 120. For example, the second cover member 220 at least partially covers the second back cover 126 of the second housing 120. In yet another embodiment, the second cover member 220 may include the third portion 221 that covers at least a portion of the back surface 120B of the second housing 120 and the fourth portion 222 that covers at least a portion of the side surface 120C of the second housing 120. The fourth portion 222 may extend from at least a portion of the edge of the third portion 221. The third portion 221 may at least partially face the second back cover 126 of the second housing 120. In yet another embodiment, a recessed second recess may be formed in a second inner surface 225 of the third portion 221. A second protrusion 228 may be formed in a second recess 227. For example, the second protrusion 228 protrudes toward the second housing 120 of the electronic device. The second protrusion 228 forms the same plane as the second inner surface 225, which is a surrounding region of the second recess 227. For example, the second protrusion 228 may protrude to the same height as the surrounding region of the second recess 227. The second recess 227 may be recessed to a predetermined depth to form the same plane as the surrounding region of the second recess 227 in a state in which a second region 242 of the inner cover 240 is seated. For example, the second recess 227 is recessed to a depth corresponding to the thickness of the second region 242.

In an embodiment, the inner cover 240 may include the first region 241, the second region 242, a third region 243, the ring 244, and a coupling portion 245.

The first region 241, the second region 242, the third region 243, the ring 244, and the coupling portion 245 illustrated in FIGS. 12 to 14 may be referred to as the first region 231, the second region 232, the third region 233, the ring 234, and the coupling portion 235, which have been illustrated in FIGS. 3 to 11.

For example, the ring 244 is exposed in the rear direction (e.g., the −Z-axis direction) through a space between the first cover member 210 and the second cover member 220. For example, the third region 243 includes an at least partially flexible region (e.g., the flexible region 233b in FIG. 4), and its shape may be changed according to folding and unfolding operations of the electronic device.

In yet another embodiment, the first region 241 may be positioned between the first housing 110 and the first cover member 210. For example, the first region 241 is disposed between the first back cover 116 of the first housing 110 and the first portion 211 of the first cover member 210. The first region 241 may be connected to the second region 242 through the third region 243. When viewed in the rear direction (e.g., the −Z-axis direction), the first region 241 may be formed to be smaller than the first portion 211 of the first housing 110.

In yet another embodiment, the first region 241 of the inner cover 240 may be seated in the first recess 217 of the first cover member 210. A first opening region 247 may be formed in the first region 241. The first opening region 247 may be formed in a shape corresponding to the first protrusion 218 of the first cover member 210. The first protrusion 218 may be inserted into the first opening region 247 of the first region 241.

In yet another embodiment, the second region 242 may be positioned between the second housing 120 and the second cover member 220. For example, the second region 242 is disposed between the second back cover 126 of the second housing 120 and the third portion 221 of the second cover member 220. The second region may be connected to the first region 241 through the third region 243. When viewed in the rear direction (the −Z-axis direction), the second region 242 may be formed to be smaller than the third portion 221 of the second housing 120.

In yet another embodiment, the second region 242 of the inner cover 240 may be seated in the second recess 227 of the second cover member 220. A second opening region 248 may be formed in the second region 242. The second opening region 248 may be formed in a shape corresponding to the second protrusion 228 of the second cover member 220. The second protrusion 228 may be inserted into the second opening region 248 of the second region 242.

In yet another embodiment, the third region 243 may connect the first region 241 and the second region 242. The third region 243 may extend across the space between the first cover member 210 and the second cover member 220. The ring 244 may be coupled to the third region 243. The third region 243 may include the coupling portion 245 surrounding a portion of the ring 244. For example, the coupling portion 245 is formed in a completely closed ring shape, or may be formed in a partially open ring shape. The coupling portion 245 may be exposed in the rear direction (e.g., the −Z-axis direction) through a space between the first cover member 210 and the second cover member 220.

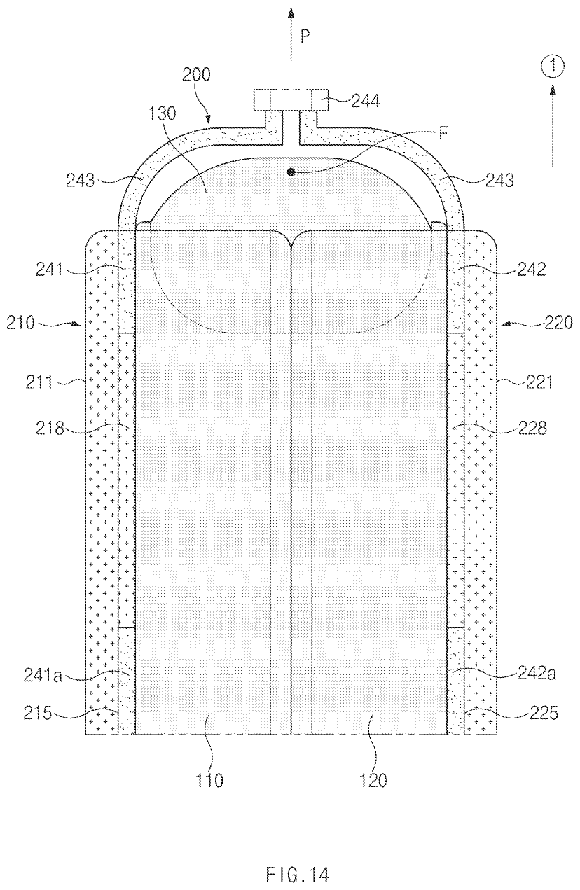

FIG. 14 is a view illustrating a folded state in which an electronic device is coupled to the cover for an electronic device according to an embodiment of the disclosure.

Referring to FIG. 14, in the folded state, the hinge housing 130 may constitute a portion of the surface of the electronic device 100. The hinge housing 130 may be exposed to a space between the first cover member 210 and the second cover member 220. At least a portion (e.g., the flexible region 233b in FIG. 4) of the third region 243 of the inner cover 240 may be disposed to partially cover the hinge housing 130 of the electronic device 100. In FIG. 14, the hinge housing 130 and the third region 243 of the inner cover 240 are illustrated as being spaced apart, but the configuration is not necessarily limited thereto, and for example, the third region 243 of the inner cover 240 may partially contact the hinge housing 130.

In yet another embodiment, a user may hold the electronic device 100 by hooking his or her finger on the ring 244. In this case, a load P may be applied to the ring 244 in a first direction (e.g., the first direction \textcircled{1} in FIG. 10). The load P may be transmitted to the first region 241 and the second region 242 of the inner cover through the third region 243. For example, the load may be applied to each of the first region 241 and the second region 242 in the first direction \textcircled{1}. For example, the first direction Di means a direction in which the first cover member 210 and the second cover member 220 are open in the folded state (e.g., a direction in which the second portion 212 and the fourth portion 222 are not formed). In various embodiments, the first direction \textcircled{1} may mean a direction substantially opposite to the direction of gravity.

When viewed in a cross-sectional view of FIG. 14, a portion 241a of the first region 241 of the inner cover 240 may not move in the first direction \textcircled{1} by the first protrusion 218 protruding from the first inner surface 215 of the first cover member 210. For example, by inserting the first protrusion 218 into the first opening region 247 of the first region 241, the position of the first region 241 is fixed despite the load P. For example, the first protrusion 218 is referred to as the first side wall 213 in FIG. 11.

Referring to FIG. 14, when the user hooks his or her finger on the ring 244 and lifts and holds the electronic device 100 lying on the ground, gravity may be applied to the first cover member 210 in the direction opposite to the first direction \textcircled{1}.

The first cover member 210 may slip down from the first housing 110 of the electronic device 100 due to the gravity. In yet another embodiment, the first protrusion 218 provided inside the first cover member 210 may transmit a load applied to the first region 241 of the inner cover 240 in the first direction \textcircled{1} to the first cover member 210, thereby pressing the first cover member 210 in the first direction \textcircled{1} as well, and thus the first cover member 210 may be prevented from sliding down from the first housing 110.

When viewed in the cross-sectional view of FIG. 14, a portion 242a of the second region 242 of the inner cover 240 may not move in the first direction \textcircled{1} by the second protrusion 228 protruding from the second inner surface 225 of the second cover member 220. For example, by inserting the second protrusion 228 into the second opening region 248 of the second region 242, the position of the second region 242 is fixed despite the load P. For example, the second protrusion 228 is referred to as the third side wall 223 in FIG. 11.

Referring to FIG. 14, when the user hooks his or her finger on the ring 244 and lifts and holds the electronic device 100 lying on the ground, gravity may be applied to the second cover member 220 in a direction opposite to the first direction \textcircled{1}. The second cover member 220 may slip down from the second housing 120 of the electronic device 100 due to the gravity. In yet another embodiment, the second protrusion 228 provided inside the second cover member 220 may transmit a load applied to the second region 242 of the inner cover 240 in the first direction \textcircled{1} to the second cover member 220, thereby pressing the second cover member 220 in the first direction \textcircled{1}, and thus the second cover member 220 may be prevented from sliding down from the second housing 120.

As described above, the cover 200 according to the embodiments disclosed herein may be easily held by a user by providing the ring 244. In addition, the cover 200 may be configured so that the two cover members 210 and 220 are firmly coupled without slipping down from two housings 110 and 120 of the electronic device 100, respectively, using the load applied to the ring 244.

A cover according to embodiments disclosed herein may include a first cover member and a second cover member that are spaced apart at a predetermined interval and configured to be folded and unfolded with a folding axis therebetween, an inner cover including a first region coupled to a first inner surface of the first cover member, a second region coupled to a second inner surface of the second cover member, and a third region extending across the predetermined interval while connecting the first region and the second region, and a ring coupled to the third region of the inner cover.

In various embodiments, the first region and the second region may be formed as a plane in each of a folded state and an unfolded state, and the third region may include a flexible region whose shape is deformed when the first cover member and the second cover member are folded or unfolded.

In various embodiments, the third region may include a first rigid region connected to the first region and a second rigid region connected to the second region, and the flexible region may be formed between the first rigid region and the second rigid region.

In various embodiments, the first region and the second region may have a first width measured in a direction of the folding axis, the third region may have a second width measured in the direction of the folding axis, and the second width may be smaller than the first width.

In various embodiments, the third region may extend in a direction substantially perpendicular to the folding axis.

In various embodiments, a first side wall contacting at least a portion of an edge of the first region of the inner cover and extending in a direction substantially parallel to the folding axis may be formed on the first inner surface, and a second side wall contacting at least a portion of an edge of the second region of the inner cover and extending in a direction substantially parallel to the folding axis may be formed on the second inner surface.

In various embodiments, the ring may be configured to allow a user's finger to be at least partially inserted.

In various embodiments, each of the first side wall and the second side wall may include a partially open region, and the third region may extend through the open region.

In various embodiments, a first recess in which the first region is at least partially accommodated may be formed on the first inner surface, and a second recess in which the second region is at least partially accommodated may be formed on the second inner surface.

In various embodiments, the first side wall may form at least a portion of the first recess, and the second side wall may form at least a portion of the second recess.

In various embodiments, the first cover member may be provided with its first edge adjacent to the folding axis is opened, the first side wall may be formed adjacent to the first edge, the second cover member may be provided with its second edge adjacent to the folding axis is opened, and the second side wall may be formed adjacent to the second edge.

In various embodiments, the ring may include a curved section and a straight section, and the third region of the inner cover may extend to at least partially surround the straight section.

According to embodiments disclosed herein, a cover for an electronic device including a folded state in which a first housing and a second housing face each other and an unfolded state in which the first housing and the second housing are arranged side by side is disclosed. The cover may include a first cover member configured to be coupled to the first housing, a second cover member configured to be coupled to the second housing, the second cover member being spaced apart from the first cover member at a predetermined distance, an inner cover including a first region positioned between the first housing and the first cover member, a second region positioned between the second housing and the second cover member, and a third region extending from the first region to the second region, and a ring coupled to the third region, and the third region of the inner cover may include a flexible region to which the ring is coupled and that is configured so that its shape is deformed when the electronic device is folded and unfolded.

In various embodiments, the electronic device may include a hinge housing disposed between the first housing and the second housing, and in the folded state, the third region of the inner cover and the hinge housing may be configured to face each other.

In various embodiments, the ring and at least a portion of the flexible region may be positioned toward a back surface of the electronic device through a gap between the first cover member and the second cover member.

In various embodiments, the first cover member may include a first inner surface at least partially in contact with the first region of the inner cover, a first side wall supporting an edge of the first region of the inner cover may be formed on the first inner surface, the second cover member may include a second inner surface at least partially in contact with the second region of the inner cover, and a second side wall supporting an edge of the second region of the inner cover may be formed on the second inner surface.

In various embodiments, the first side wall may be formed at an edge adjacent to the second cover member among edges of the first cover member, and the second side wall may be formed at an edge adjacent to the first cover member among edges of the second cover member.

In various embodiments, the first cover member and the second cover member may be configured to be folded and unfolded with a folding axis therebetween, and the first side wall and the second side wall may be parallel to the folding axis.

In various embodiments, each of the first side wall and the second side wall may include a partially open region, and the third region may extend through the open region.

In various embodiments, the first region and the second region may have a first width measured in a direction of the folding axis, the third region may have a second width measured in the direction of the folding axis, and the second width may be smaller than the first width.

It should be appreciated that various embodiments of the disclosure and the terms used therein are not intended to limit the technology set forth herein to particular embodiments and include various changes, equivalents, and/or replacements for a corresponding embodiment. With regard to the description of the drawings, similar reference numerals may be used to refer to similar elements. As used herein, the phrases “A or B”, “at least one of A and/or B”, “A, B, or C”, or “one or more of A, B, and/or C” may include all possible combinations of the items listed together. The terms such as “first”, “second”, “the first”, or “the second” may modify corresponding components, regardless of order or importance, and are used to distinguish one component from another, but do not limit the components. When a certain (e.g., first) component is referred to as being “(functionally or communicatively) coupled” or “connected” to another (e.g., second) component, it is to be understood that the certain component may be directly connected to the other component, or may be connected through any other component (e.g., third component).

As used here, the phrase “adapted to” or “configured to” may be interchangeably used with “suitable for”, “having a capacity to”, “modified to”, “made to”, “capable of” or “designed to” depending on circumstances, for example, in terms of hardware or software. In some circumstances, the phrase “device configured to” may mean that the device “can” perform an operation with other devices or parts. For example, the phrase “processor adapted (or configured) to perform A, B, and C” means a dedicated processor (e.g., embedded processor) for performing corresponding operations, or a generic-purpose processor (e.g., central processing unit (CPU) or application processor (AP)) that performs the operations by executing one or more programs stored in a memory device (e.g., a memory).

As used herein, the term “module” may include a unit constituted by hardware, software, or firmware, and may interchangeably be used with other terms, for example, “logic,” “logic block,” “part,” or “circuitry”. A “module” may be a single integral component, or a minimum unit or part adapted to perform one or more functions. The “module” may be implemented mechanically or electronically, and may include, for example, at least one of an application-specific integrated circuit (ASIC) chip, a field-programmable gate array (FPGA), or a programmable-logic device that performs certain operations, which has been known, or will be developed in the future.

At least part of a device (e.g., modules or functions thereof) or method (e.g., operations) according to various embodiments may be implemented using instructions stored in a computer-readable storage medium (e.g., a memory) in the form of a program module. When the instructions are executed by a processor, the processor may perform functions corresponding to the instructions. The computer-readable storage medium may include a hard disk, a floppy disk, a magnetic medium (e.g., a magnetic tape), an optical recording medium (e.g., compact disc read only memory (CD-ROM), digital versatile disc (DVD), magneto-optical medium (e.g., a floptical disk), built-in memory, or the like. Instructions may include code generated by a compiler or code capable of being executed by an interpreter.

Each of components (e.g., a module or a program module) according to various embodiments may be made up of a singular or a plurality of entities, and may omit some of the aforementioned sub-components or further include other sub-components. Alternatively or additionally, some components (e.g., a module or a program module) may be integrated into one entity, performing the same or similar functions performed by respective corresponding components before integration. According to various embodiments, operations performed by a module, program module, or another component may be sequentially, parallelly, repeatedly, or heuristically executed, at least some operations may be executed in a different order, omitted, or other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

1. A cover for an electronic device, the cover comprising:
a first cover member and a second cover member that are spaced apart at a predetermined interval, the first cover member and the second cover member are configured to be folded and unfolded with a folding axis therebetween;
an inner cover comprising a first region coupled to a first inner surface of the first cover member, a second region coupled to a second inner surface of the second cover member, and a third region extending across the predetermined interval while connecting the first region and the second region; and
a ring coupled to the third region of the inner cover.

2. The cover of claim 1,
wherein the first region and the second region are formed as a plane in each of a folded state and an unfolded state, and
wherein the third region comprises a flexible region whose shape is deformed when the first cover member and the second cover member are folded or unfolded.

3. The cover of claim 2,
wherein the third region further comprises a first rigid region connected to the first region and a second rigid region connected to the second region, and
wherein the flexible region is formed between the first rigid region and the second rigid region.

4. The cover of claim 1,
wherein the first region and the second region have a first width measured in a direction of the folding axis,
wherein the third region has a second width measured in the direction of the folding axis, and
wherein the second width is smaller than the first width.

5. The cover of claim 1, wherein the third region extends in a direction substantially perpendicular to the folding axis.

6. The cover of claim 1,
wherein a first side wall contacting at least a portion of an edge of the first region of the inner cover and extending in a direction substantially parallel to the folding axis is formed on the first inner surface, and
wherein a second side wall contacting at least a portion of an edge of the second region of the inner cover and extending in a direction substantially parallel to the folding axis is formed on the second inner surface.

7. The cover of claim 6,
wherein each of the first side wall and the second side wall comprises a partially open region, and
wherein the third region extends through the partially open region.

8. The cover of claim 7,
wherein a first recess in which the first region is at least partially accommodated is formed on the first inner surface, and
wherein a second recess in which the second region is at least partially accommodated is formed on the second inner surface.

9. The cover of claim 8,
wherein the first side wall forms at least a portion of the first recess, and
wherein the second side wall forms at least a portion of the second recess.

10. The cover of claim 6,
wherein the first cover member is provided with its first edge adjacent to the folding axis is opened,
wherein the first side wall is formed adjacent to the first edge,
wherein the second cover member is provided with its second edge adjacent to the folding axis is opened, and
wherein the second side wall is formed adjacent to the second edge.

11. The cover of claim 1,
wherein the ring comprises a curved section and a straight section, and
wherein the third region of the inner cover extends to at least partially surround the straight section.

12. The cover of claim 1,
wherein a folded state in which a first housing and a second housing of the electronic device face each other and an unfolded state in which the first housing and the second housing are arranged side by side are included,
wherein the first cover member is configured to be coupled to the first housing,
wherein the second cover member is configured to be coupled to the second housing and is spaced apart from the first cover member at a predetermined interval,
wherein the first region of the inner cover is positioned between the first housing and the first cover member,
wherein the second region of the inner cover is positioned between the second housing and the second cover member, and
wherein the third region of the inner cover comprises a flexible region configured to change a shape depending on the folded state or the unfolded state.

13. The cover of claim 12, wherein the electronic device comprises:
a hinge housing disposed between the first housing and the second housing; and
in the folded state, the third region of the inner cover and the hinge housing are configured to face each other.

14. The cover of claim 12, wherein the ring and at least a portion of the flexible region are positioned toward a back surface of the electronic device through a gap between the first cover member and the second cover member.

15. The cover of claim 12,
wherein the first cover member includes:
a first inner surface at least partially in contact with the first region of the inner cover, and
a first side wall supporting an edge of the first region of the inner cover formed on the first inner surface,
wherein the second cover member includes:
a second inner surface at least partially in contact with the second region of the inner cover, and
a second side wall supporting an edge of the second region of the inner cover formed on the second inner surface,
wherein the first side wall is formed at an edge adjacent to the second cover member among edges of the first cover member, and
wherein the second side wall is formed at an edge adjacent to the first cover member among edges of the second cover member.

16. The cover of claim 1, wherein the ring is configured to allow a user's finger to be at least partially inserted.

17. The cover of claim 15,
wherein the first cover member and the second cover member are configured to be folded and unfolded with a folding axis therebetween, and
wherein the first side wall and the second side wall are parallel to the folding axis.

18. The cover of claim 15, wherein each of the first side wall and the second side wall include a partially open region.

19. The cover of claim 18, wherein the third region extends through the partially open region.

20. The cover of claim 12,
wherein the first region and the second region have a first width measured in a direction of the folding axis,
wherein the third region has a second width measured in the direction of the folding axis, and
wherein the second width is smaller than the first width.
